(19) United States
(12) Patent Application Publication
(10) Pub. No.: US 2017/0229437 A1
(43) Pub. Date: Aug. 10, 2017

(54) OPTOELECTRONIC COMPONENT DEVICE AND METHOD FOR PRODUCING AN OPTOELECTRONIC COMPONENT DEVICE

(71) Applicant: OSRAM OLED GmbH, Regensburg (DE)

(72) Inventors: Thomas Wehlus, Lappersdorf (DE); Daniel Riedel, Regensburg (DE); Nina Riegel, Tegernheim (DE); Silke Scharner, Regensburg (DE); Johannes Rosenberger, Regensburg (DE); Arne Fleissner, 93059 (DE)

(21) Appl. No.: 15/502,519

(22) PCT Filed: Jul. 31, 2015
(86) PCT No.: PCT/EP2015/067743

§ 371 Date: Feb. 8, 2017

(30) Foreign Application Priority Data
Aug. 8, 2014 (DE) 10 2014 111 346.2

(51) Int. Cl. H01L 25/16; H01L 31/0216; H01L 51/50; H01L 33/60; H01L 31/0232; H01L 51/52; H01L 31/167; H01L 33/58; H01L 31/0203; H01L 51/00

(52) U.S. Cl. CPC H01L 25/167; H01L 31/0203; H01L 31/02162; H01L 51/5048; H01L 51/0001; H01L 31/02325; H01L 51/52; H01L 31/167; H01L 33/58; H01L 33/60; H01L 25/0753

(57) ABSTRACT

In various exemplary embodiments, an optoelectronic component device is provided. The optoelectronic component device includes a first organic light emitting diode and a second organic light emitting diode, which are connected to one another in physical contact one above the other. The first organic light emitting diode is electrically connected in parallel with the second organic light emitting diode. The first organic light emitting diode and the second organic light emitting diode have at least an approximately identical or identical electronic diode characteristic and/or an approximately identical or identical electronic diode characteristic variable.

### RELATED APPLICATIONS

The present application is a national stage entry according to 35 U.S.C. §371 of PCT application No.: PCT/EP2015/067743 filed on Jul. 31, 2015, which claims priority from German application No.: 10 2014 111 346.2 filed on Aug. 8, 2014, and is incorporated herein by reference in its entirety.

### TECHNICAL FIELD

Various embodiments relate to an optoelectronic component device and to a method for producing an optoelectronic component device.

### BACKGROUND

The lifetime of an OLED can conventionally be increased by an OLED being multiply stacked. For this purpose, color units are connected by means of a so-called CGL (charge generation layer). They are connected in series, as it were. The required voltage by means of which the OLED can be operated rises as a result. It is increased n-fold by the stacking of n units. However, it is often expedient not to exceed certain limits with the voltage. For example 12 volts in the case of use in automobile on-board electrical systems or 35 volts in low-power electrical systems.

### SUMMARY

Various embodiments provide a more efficient optoelectronic component device having an increased lifetime.

Various embodiments are achieved in accordance with one aspect of the disclosure by means of an optoelectronic component device including a first organic light emitting diode and a second organic light emitting diode, which are connected to one another in physical contact one above the other. The first organic light emitting diode is electrically connected in parallel with the second organic light emitting diode. The first organic light emitting diode and the second organic light emitting diode have at least an approximately identical or identical electronic diode characteristic and/or an approximately identical or identical electronic diode characteristic variable. This makes it possible to provide a more efficient optoelectronic component device having an increased lifetime.

Various embodiments are achieved in accordance with a further aspect of the disclosure by means of an optoelectronic component device including a first organic light emitting diode and a second organic light emitting diode, which are connected to one another in physical contact one above the other. The first organic light emitting diode is electrically connected in parallel with the second organic light emitting diode. The first organic light emitting diode provides a first light having a first hue and the second organic light emitting diode provides a second light having a second hue. The first hue and the second hue are approximately identical or identical. This makes it possible to provide a more efficient optoelectronic component device having an increased lifetime.

In accordance with one development, the optoelectronic component device includes one or a plurality of further organic light emitting diodes connected in series with the first organic light emitting diode. This makes it possible to provide an optoelectronic component device having a higher lifetime.

In accordance with one development, the optoelectronic component device includes one or a plurality of further organic light emitting diodes connected in series with the second organic light emitting diode. This makes it possible to provide an optoelectronic component device having a higher lifetime.

In accordance with one development, the first organic light emitting diode includes a first electrode, an organic functional layer structure and a second electrode, wherein the organic functional layer structure is arranged on or above the first electrode and wherein the second electrode is arranged on or above the organic functional layer structure. The lifetime of the optoelectronic component device can be increased further as a result.

In accordance with one development, the second organic light emitting diode includes a first electrode, an organic functional layer structure and a second electrode, wherein the organic functional layer structure is arranged on or above the first electrode and wherein the second electrode is arranged on or above the organic functional layer structure. The lifetime of the optoelectronic component device can be increased further as a result.

In accordance with one development, the second electrode of the first organic light emitting diode and the first electrode of the second organic light emitting diode are electrically connected to one another in such a way that they form a common electrode. As a result, the lifetime of the optoelectronic component device can be increased even further.

In accordance with one development, the common electrode is formed from or includes an at least translucent material. As a result, the lifetime of the optoelectronic component device can be increased even further.

In accordance with one development, the second electrode of the first organic light emitting diode is an anode of the first organic light emitting diode and the first electrode of the second organic light emitting diode is an anode of the second organic light emitting diode. The lifetime of the optoelectronic component device can be increased even further as a result.

In accordance with one development, the first electrode of the first organic light emitting diode and the second electrode of the second organic light emitting diode have a common electrical potential. As a result, the lifetime of the optoelectronic component device can be increased even further.

In accordance with one development, the first electrode of the first organic light emitting diode and the second electrode of the second organic light emitting diode are arranged congruently one above the other, and the second electrode of the first organic light emitting diode and the first electrode of the second organic light emitting diode are arranged congruently one above the other. As a result, the lifetime of the optoelectronic component device can be increased even further.

Various embodiments are achieved in accordance with a further aspect of the disclosure by means of a method for producing an optoelectronic component device, including forming a first organic light emitting diode and a second organic light emitting diode in such a way that the first organic light emitting diode and the second organic light emitting diode are connected to one another in physical contact one above the other. The first organic light emitting diode is electrically connected in parallel with the second organic light emitting diode. The first organic light emitting diode and the second organic light emitting diode are formed in such a way that they have at least an approximately identical or identical electronic diode characteristic and/or an approximately identical or identical electronic diode characteristic variable. This makes it possible to produce a more efficient optoelectronic component device having an increased lifetime.

Various embodiments are achieved in accordance with a further aspect of the disclosure by means of a method for producing an optoelectronic component device, including forming a first organic light emitting diode and a second organic light emitting diode in such a way that the first organic light emitting diode and the second organic light emitting diode are connected to one another in physical contact one above the other. The first organic light emitting diode is electrically connected in parallel with the second organic light emitting diode. The first organic light emitting diode is formed in such a way that it provides a first light having a first hue and the second organic light emitting diode is formed in such a way that it provides a second light having a second hue. The first organic light emitting diode and the second organic light emitting diode are formed in such a way that the first hue and the second hue are approximately identical or identical. This makes it possible to produce a more efficient optoelectronic component device having an increased lifetime.

In accordance with one development, the method furthermore includes forming one or a plurality of further organic light emitting diodes connected in series with the first organic light emitting diode. This makes it possible to produce an optoelectronic component device having an even higher lifetime.

In accordance with one development, the method furthermore includes forming one or a plurality of further organic light emitting diodes connected in series with the second organic light emitting diode. This makes it possible to produce an optoelectronic component device having an even higher lifetime.

In accordance with one development, forming the first organic light emitting diode includes forming a first electrode, forming an organic functional layer structure and forming a second electrode, wherein the organic functional layer structure is arranged on or above the first electrode and wherein the second electrode is arranged on or above the organic functional layer structure. This makes it possible to produce an optoelectronic component device having an even higher lifetime.

In accordance with one development, forming the second organic light emitting diode includes forming a first electrode, forming an organic functional layer structure and forming a second electrode, wherein the organic functional layer structure is arranged on or above the first electrode and wherein the second electrode is arranged on or above the organic functional layer structure. This makes it possible to produce an optoelectronic component device having an even higher lifetime.

In accordance with one development, the second electrode of the first organic light emitting diode and the first electrode of the second organic light emitting diode are electrically connected to one another in such a way that they form a common electrode. This makes it possible to produce an optoelectronic component device having an even higher lifetime.

In accordance with one development, the common electrode is formed from an at least translucent material or is formed in such a way that the common electrode includes a translucent material. This makes it possible to produce an optoelectronic component device having an even higher lifetime.

In accordance with one development, the first electrode of the first organic light emitting diode and the second electrode of the second organic light emitting diode are arranged congruently one above the other, and the second electrode of the first organic light emitting diode and the first electrode of the second organic light emitting diode are arranged congruently one above the other. This makes it possible to produce an optoelectronic component device having an even higher lifetime.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1A shows a sectional illustration of an organic light emitting diode;

FIG. 1B shows a sectional illustration of a part of an organic light emitting diode;

FIG. 2 shows a sectional illustration of one exemplary embodiment of an optoelectronic component device;

FIG. 3 shows an equivalent circuit diagram of one exemplary embodiment of an optoelectronic component device;

FIG. 4 shows an equivalent circuit diagram of one exemplary embodiment of an optoelectronic component device;

FIG. 5 shows a schematic illustration of one exemplary embodiment of an optoelectronic component device; and

FIG. 6 shows a flow diagram of a method for producing an optoelectronic component device.

### DETAILED DESCRIPTION

In the following detailed description, reference is made to the accompanying drawings, which form part of this description and show for illustration purposes specific exemplary embodiments in which various embodiments can be implemented. In this regard, direction terminology such as, for instance, “at the top”, “at the bottom”, “at the front”, “at the back”, “front”, “rear”, etc. is used with respect to the orientation of the figure(s) described. Since component parts of exemplary embodiments can be positioned in a number of different orientations, the direction terminology serves for illustration and is not restrictive in any way whatsoever. It goes without saying that other exemplary embodiments can be used and structural or logical changes can be made, without departing from the scope of protection of the present disclosure. It goes without saying that the features of the various exemplary embodiments described herein can be combined with one another, unless specifically indicated otherwise. Therefore, the following detailed description should not be interpreted in a restrictive sense, and the scope of protection of the present disclosure is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

An organic optoelectronic component may include one, two or more organic optoelectronic components. Optionally, an organic optoelectronic component can also include one, two or more electronic components. An electronic component may include for example an active and/or a passive component. An active electronic component may include for example a computing, control and/or regulating unit and/or a transistor. A passive electronic component may include for example a capacitor, a resistor, a diode or a coil.

An organic optoelectronic component can be an electromagnetic radiation emitting component. In various exemplary embodiments, an electromagnetic radiation emitting component can be an electromagnetic radiation emitting semiconductor component and/or in the form of an electromagnetic radiation emitting diode, an organic electromagnetic radiation emitting diode. The radiation can be for example light in the visible range, UV light and/or infrared light. In various exemplary embodiments, the light emitting component can be part of an integrated circuit. Furthermore, a plurality of light emitting components can be provided, for example in a manner accommodated in a common housing.

In various exemplary embodiments, the term “translucent” or “translucent layer” can be understood to mean that a layer is transmissive to light, for example to the light generated by the light emitting component, for example in one or more wavelength ranges, for example to light in a wavelength range of visible light (for example at least in a partial range of the wavelength range of 380 nm to 780 nm). By way of example, in various exemplary embodiments, the term “translucent layer” should be understood to mean that substantially the entire quantity of light coupled into a structure (for example a layer) is also coupled out from the structure (for example layer), wherein part of the light can be scattered in this case.

In various exemplary embodiments, the organic light emitting diode (or else the light emitting components in accordance with the exemplary embodiments described above or those that will be described below) can be designed as a so-called top and bottom emitter. A top and/or bottom emitter can also be referred to as an optically transparent component, for example a transparent organic light emitting diode.

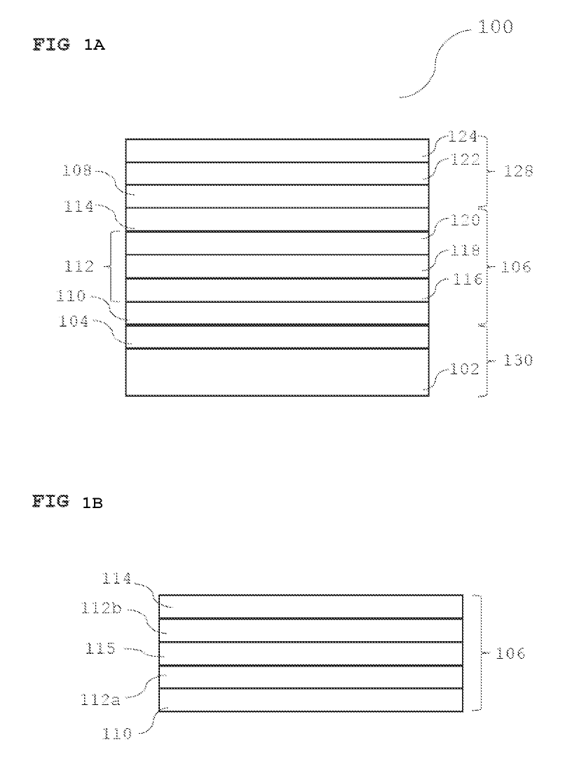

FIG. 1A shows a sectional view of an organic light emitting diode 100. The organic light emitting diode 100 includes a carrier 102, for example also referred to as substrate 102. The carrier 102 serves as carrier element for electronic elements, layers and/or light emitting elements. A barrier layer 104 is arranged on or above the carrier 102. The carrier 102 and the barrier layer 104 together form a hermetically impermeable substrate 130. An active region 106 is arranged on or above the hermetically impermeable substrate 130. The active region 106 is an electrically active region 106 and/or an optically active region 106. The active region 106 is for example that region of the optoelectronic component 100 in which electric current for the operation of the optoelectronic component 100 flows and/or in which electromagnetic radiation is generated. An encapsulation structure 128 is arranged on or above the active region 106. The hermetically impermeable substrate 102, the active region 106 and the encapsulation structure 128 will be described thoroughly below.

The electrically active region 106 includes a first electrode 110, an organic functional layer structure 112 and a second electrode 114. The first electrode 110 is an anode, that is to say in the form of a hole-injecting electrode, of the organic light emitting diode 100. The second electrode is a cathode, that is to say in the form of an electron-injecting electrode, of the organic light emitting diode 100. The organic functional layer structure includes a hole injection layer (not shown) arranged on the first electrode 110. A hole transport layer 116 (also referred to as hole conducting layer 116) is formed on the hole injection layer. Furthermore, an emitter layer 118 is arranged on the hole transport layer 116. An electron transport layer 120 (also referred to as electron conducting layer 120) is arranged on the emitter layer 118. An electron injection layer (not shown) is formed on the electron transport layer 120.

Alternatively or additionally, the carrier 102 may include or be formed from glass, quartz and/or a semiconductor material. Furthermore, the carrier may include or be formed from a plastics film or a laminate including one or including a plurality of plastics films. The plastic may include or be formed from one or a plurality of polyolefins (for example high or low density polyethylene (PE) or polypropylene (PP)).

Furthermore, the plastic may include or be formed from polyvinyl chloride (PVC), polystyrene (PS), polyester and/or polycarbonate (PC), polyethylene terephthalate (PET), polyethersulfone (PES) and/or polyethylene naphthalate (PEN).

Alternatively or additionally, the carrier 102 may include or be formed from a metal, for example copper, silver, gold, platinum, iron, for example a metal compound, for example steel.

Alternatively or additionally, the carrier 102 can be embodied as opaque, translucent or even transparent.

Alternatively or additionally, the carrier 102 can be a part of a mirror structure or form the latter.

Alternatively or additionally, the carrier 102 can have a mechanically rigid region and/or a mechanically flexible region or be formed in this way, for example as a film.

Alternatively or additionally, the carrier 102 can be formed as a waveguide for electromagnetic radiation, for example can be transparent or translucent with respect to the emitted or absorbed electromagnetic radiation of the optoelectronic component 100.

Alternatively or additionally, the optoelectronic component device can also be formed without a carrier 102, for example in the case where one of the electrodes is formed in a self-supporting manner; by way of example, the self-supporting electrode can serve as a carrier 102 in this case.

The first barrier layer 104 may include or be formed from one of the following materials: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, poly(p-phenylene terephthalamide), nylon 66, and mixtures and alloys thereof.

Alternatively or additionally, the first barrier layer 104 can be formed by means of one of the following methods: an atomic layer deposition (ALD) method, for example a plasma enhanced atomic layer deposition (PEALD) method or a plasmaless atomic layer deposition (PLALD) method; a chemical vapor deposition (CVD) method, for example a plasma enhanced chemical vapor deposition (PECVD) method or a plasmaless chemical vapor deposition (PLCVD) method; or alternatively by means of other suitable deposition methods.

Alternatively or additionally, in the case of a first barrier layer 104 including a plurality of partial layers, all the partial layers can be formed by means of an atomic layer deposition method. A layer sequence including only ALD layers can also be designated as a “nanolaminate”.

Alternatively or additionally, in the case of a first barrier layer 104 including a plurality of partial layers, one or a plurality of partial layers of the first barrier layer 104 can be deposited by means of a different deposition method than an atomic layer deposition method, for example by means of a vapor deposition method.

Alternatively or additionally, the first barrier layer 104 can have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

Alternatively or additionally, the first barrier layer 104 may include one or a plurality of high refractive index materials, for example one or a plurality of materials having a high refractive index, for example having a refractive index of at least two.

Furthermore, it should be pointed out that, in various exemplary embodiments, a first barrier layer 104 can also be entirely dispensed with, for example for the case where the carrier 102 is formed in a hermetically impermeable fashion, for example includes or is formed from glass, metal, metal oxide.

Alternatively, the first electrode 210 can be formed as a cathode.

Alternatively or additionally, the first electrode 110 may include or be formed from one of the following electrically conductive materials: a metal; a transparent conductive oxide (TCO); a network composed of metallic nanowires and nanoparticles, for example composed of Ag, which are combined with conductive polymers, for example; a network composed of carbon nanotubes which are combined with conductive polymers, for example; graphene particles and graphene layers; a network composed of semiconducting nanowires; an electrically conductive polymer; a transition metal oxide; and/or the composites thereof. The first electrode 110 composed of a metal or including a metal may include or be formed from one of the following materials: Ag, Pt, Au, Mg, Al, Ba, In, Ca, Sm or Li, and compounds, combinations or alloys of these materials. The first electrode 110 may include as transparent conductive oxide one of the following materials: for example metal oxides: for example zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs and can be used in various exemplary embodiments. Furthermore, the TCOs do not necessarily correspond to a stoichiometric composition and can furthermore be p-doped or n-doped or be hole-conducting (p-TCO), or electron-conducting (n-TCO).

Alternatively or additionally, the first electrode 110 may include a layer or a layer stack of a plurality of layers of the same material or different materials. The first electrode 110 can be formed by a layer stack of a combination of a layer of a metal on a layer of a TCO, or vice versa. One example is a silver layer applied on an indium tin oxide layer (ITO) (Ag on ITO) or ITO-Ag-ITO multilayers.

Alternatively or additionally, the first electrode 110 can have a layer thickness in a range of 10 nm to 500 nm, of less than 25 nm to 250 nm, for example of 50 nm to 100 nm.

Alternatively or additionally, the first electrode 110 can have an electrical terminal, to which an electrical potential can be applied. The electrical potential can be provided by an energy source, for example a current source or a voltage source. Alternatively, the electrical potential can be applied to an electrically conductive carrier 102 and the first electrode 110 can be electrically supplied indirectly through the carrier 102. The electrical potential can be for example the ground potential or some other predefined reference potential.

Alternatively or additionally, the carrier 102 can be formed from or include a conductive substance and/or the carrier 102 can be coated with a conductive substance, for example with a conductive substance as described thoroughly above. By way of example, the carrier 102 can be the electrode 110 in this case.

Alternatively or additionally, a scattering layer can be arranged on the first electrode 110. The scattering layer is for example formed from or includes a translucent or transparent material. The scattering layer includes particles that scatter electromagnetic radiation, for example light-scattering particles. This results in an improvement in the color angle distortion and the coupling-out efficiency.

Alternatively or additionally, the hole injection layer may include or be formed from one or a plurality of the following materials: HAT-CN, Cu(I)pFBz, MoOₓ, WOₓ, VO_{N}, ReOₓ, F4-TCNQ, NDP-2, NDP-9, Bi(III)pFBz, F16CuPc; NPB (N,N′-bis(naphthalen-1-yl)-N,N′-bis(phenyl)benzidine); beta-NPB N,N′-bis(naphthalen-2-yl)-N,N′-bis(phenyl)benzidine); TPD (N,N′-bis(3-methylphenyl)-N,N′-bis(phenyl)benzidine); spiro-TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetrakis(n,n-diphenylamino)-9,9′-spirobifluorene); 9,9-bis[4-(N,N-bisbiphenyl-4-yl-amino)phenyl]-9H-fluorene; 9,9-bis[4-(N,N-bis-naphthalen-2-ylamino)phenyl]-9H-fluorene; 9,9-bis[4-(N,N′-bisnaphthalen-2-yl-N,N′-bisphenylamino)phenyl]-9H-fluorene; N,N′-bis(phenanthren-9-yl)-N,N′-bis(phenyl)benzidine; 2,7-bis[N,N-bis(9,9-spirobifluoren-2-yl)amino)-9,9-spirobifluorene; 2,2′-bis[N,N-bis(biphenyl-4-yl)amino]9,9-spirobifluorene; 2,2′-bis(N,N-diphenylamino)9,9-spirobifluorene; di-[4-(N,N-ditolylamino)phenyl]cyclohexane; 2,2′,7,7′-tetra(N,N-ditolyl)aminospirobifluorene; and/or N,N,N′,N′-tetranaphthalen-2-ylbenzidine.

Alternatively or additionally, the hole injection layer can have a layer thickness in a range of approximately 10 nm to approximately 1000 nm, for example in a range of approximately 30 nm to approximately 300 nm, for example in a range of approximately 50 nm to approximately 200 nm.

Alternatively or additionally, the hole transport layer may include or be formed from one or a plurality of the following materials: NPB (N,N′-bis(naphthalen-1-yl)-N,N′-bis(phenyl)benzidine); beta-NPB N,N′-bis(naphthalen-2-yl)-N,N′-bis(phenyl)benzidine); TPD (N,N′-bis(3-methylphenyl)-N,N′-bis(phenyl)benzidine); spiro TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetrakis(n,n-diphenylamino)-9,9′-spirobifluorene); 9,9-bis[4-(N,N-bisbiphenyl-4-ylamino)phenyl]-9H-fluorene; 9,9-bis[4-(N,N′-bisnaphthalen-2-ylamino)phenyl]-9H-fluorene; 9,9-bis[4-(N,N′-bisnaphthalen-2-yl-N,N′-bisphenylamino)phenyl]-9H-fluorene; N,N′-bis(phenanthren-9-yl)-N,N′-bis(phenyl)benzidine; 2,7-bis[N,N-bis(9,9-spirobifluoren-2-yl)amino]-9,9-spirobifluorene; 2,2′-bis[N,N-bis(biphenyl-4-yl)amino]9,9-spirobifluorene; 2,2′-bis(N,N-diphenylamino)9,9-spirobifluorene; di-[4-(N,N-ditolylamino)phenyl]cyclohexane; 2,2′,7,7′-tetra(N,N-ditolyl)aminospirobifluorene; and N,N,N′,N′-tetranaphthalen-2-ylbenzidine, a tertiary amine, a carbazole derivative, a conductive polyaniline and/or polyethylene dioxythiophene.

The hole transport layer can have a layer thickness in a range of approximately 5 nm to approximately 50 nm, for example in a range of approximately 10 nm to approximately 30 nm, for example approximately 20 nm.

The emitter layer 118 may include fluorescent and/or phosphorescent emitters. Alternatively or additionally, the organic light emitting diode 100 may include a plurality of emitter layers.

Alternatively or additionally, the emitter layer may include or be formed from organic polymers, organic oligomers, organic monomers, organic small, non-polymer molecules (“small molecules”) or a combination of these materials.

Alternatively or additionally, the optoelectronic component 100 may include or be formed from one or a plurality of the following materials in an emitter layer: organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl)iridium III), green phosphorescent Ir(ppy)₃ (tris(2-phenylpyridine)iridium III), red phosphorescent Ru (dtb-bpy)₃*2(PF₆) (tris[4,4′-di-tert-butyl-(2,2′)-bipyridine]-ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]anthracene) and red fluorescent DCM2 (4-dicyanomethylene)-2-methyl-6-julolidyl-9-enyl-4H-pyran) as non-polymeric emitters.

Such non-polymeric emitters can be deposited for example by means of thermal evaporation. Furthermore, polymer emitters can be used which can be deposited for example by means of a wet-chemical method, such as, for example, a spin coating method.

Alternatively or additionally, the emitter materials can be embedded in a suitable manner in a matrix material, for example a technical ceramic or a polymer, for example an epoxy; or a silicone.

Alternatively or additionally, in various exemplary embodiments, the emitter layer has a layer thickness in a range of approximately 5 nm to approximately 50 nm, for example in a range of approximately 10 nm to approximately 30 nm, for example approximately 20 nm.

Alternatively or additionally, the emitter layer may include emitter materials that emit in one color or in different colors (for example blue and yellow or blue, green and red). Alternatively, the emitter layer may include a plurality of partial layers which emit light of different colors. By means of mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary radiation and secondary radiation.

Alternatively or additionally, the organic functional layer structure 121 may include one or a plurality of emitter layers embodied as hole transport layer.

Alternatively or additionally, the organic functional layer structure 112 may include one or more emitter layers embodied as electron transport layer.

Alternatively or additionally, the electron transport layer may include or be formed from one or a plurality of the following materials: NET-18; 2,2′,2″-(1,3,5-benzinetriyl)tris(1-phenyl-1-H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquino-linolatolithium, 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-naphthalen-2-yl)phenyl)-1H-imidazo[4,5-f][1,10]phenanthroline; phenyldipyrenylphosphine oxide; naphthalenetetracarboxylic dianhydride or the imides thereof; perylenetetracarboxylic dianhydride or the imides thereof; and substances based on silols including a silacyclopentadiene unit

Alternatively or additionally, the electron transport layer can have a layer thickness in a range of approximately 5 nm to approximately 50 nm, for example in a range of approximately 10 nm to approximately 30 nm, for example approximately 20 nm.

Alternatively or additionally, the electron injection layer may include or be formed from one or a plurality of the following materials: NDN-26, MgAg, Cs₂CO₃, Cs₃PO₄, Na, Ca, K, Mg, Cs, Li, LiF; 2,2′,2″-(1,3,5-benzinetriyl)tris(1-phenyl-1-H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolatolithium, 4-(naphthalen-1-yl)-3,5-diphenyl-4H-1,2,4-triazole; 1,3-bis[2-(2,2′-bipyridin-6-yl)-1,3,4-oxadiazo-5-yl)benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyldipyrenylphosphine oxide; naphthalenetetracarboxylic dianhydride or the imides thereof; perylenetetracarboxylic dianhydride or the imides thereof; and substances based on silols including a silacyclopentadiene unit.

Alternatively or additionally, the electron injection layer can have a layer thickness in a range of approximately 5 nm to approximately 200 nm, for example in a range of approximately 20 nm to approximately 50 nm, for example approximately 30 nm.

The optoelectronic component 100 can optionally include further organic functional layers, for example arranged on or above the one or the plurality of emitter layers or on or above the electron transport layer(s). The further organic functional layers can be for example internal or external coupling-in/coupling-out structures that further improve the functionality and thus the efficiency of the optoelectronic component 100.

Alternatively or additionally, at least one of the above-described layers of the organic functional layer structure is optional.

Alternatively or additionally, at least one of the above-described layers can be formed as a mixture of at least two of the above-described layers.

Alternatively, the second electrode 114 can be formed as an anode. Alternatively or additionally, the organic functional layer structure 112, for the case where the first electrode 110 is formed as cathode and the second electrode 114 is formed as anode, can have an opposite layer sequence.

Alternatively or additionally, the second electrode 114 can be formed in accordance with one of the configurations of the first electrode 110, wherein the first electrode 110 and the second electrode 114 can be formed identically or differently. The second electrode 114 can have a further electrical terminal, to which a further electrical potential can be applied. The further electrical potential can be provided by the same energy source as, or a different energy source than, the electrical potential. The further electrical potential can be different than the electrical potential. The further electrical potential can have for example a value such that the difference with respect to the electrical potential has a value in a range of approximately 1.5 V to approximately 20 V, for example a value in a range of approximately 2.5 V to approximately 15 V, for example a value in a range of approximately 3 V to approximately 12 V.

Alternatively or additionally, the second barrier layer 108 can be referred to as thin film encapsulation (TFE). The second barrier layer 108 can be formed in accordance with one of the configurations of the first barrier layer 104.

Furthermore, it should be pointed out that, in various exemplary embodiments, a second barrier layer 108 can also be entirely dispensed with. In such a configuration, the optoelectronic component 100 may include for example a further encapsulation structure, as a result of which a second barrier layer 108 can become optional, for example a cover 124, for example a cavity glass encapsulation or metallic encapsulation.

Alternatively or additionally, in various exemplary embodiments, in addition, one or a plurality of coupling-in/-out layers can also be formed in the optoelectronic component 100, for example an external coupling-out film on or above the carrier 102 (not illustrated) or an internal coupling-out layer (not illustrated) in the layer cross section of the organic light emitting diode 100. The coupling-in/-out layer may include a matrix and scattering centers distributed therein, wherein the average refractive index of the coupling-in/-out layer is greater than or smaller than the average refractive index of the layer from which the electromagnetic radiation is provided. Furthermore, in various exemplary embodiments, in addition, one or a plurality of antireflection layers (for example combined with the second barrier layer 108) can be provided in the organic light emitting diode 100.

Alternatively or additionally, a close connection layer 122, for example composed of an adhesive or a lacquer, can be arranged on or above the second barrier layer 108. By means of the close connection layer 122, a cover 124 can be closely connected, for example adhesively bonded, on the second barrier layer 108.

Alternatively or additionally, a close connection layer 122 composed of a transparent material may include for example particles which scatter electromagnetic radiation, for example light-scattering particles. As a result, the close connection layer 122 can act as a scattering layer and lead to an improvement in the color angle distortion and the coupling-out efficiency.

Alternatively or additionally, the light-scattering particles provided can be dielectric scattering particles, for example, composed of a metal oxide, for example, silicon oxide (SiO₂), zinc oxide (ZnO), zirconium oxide (ZrO₂), indium tin oxide (ITO) or indium zinc oxide (IZO), gallium oxide (Ga₂Oₓ), aluminum oxide, or titanium oxide. Other particles may also be suitable provided that they have a refractive index that is different than the effective refractive index of the matrix of the close connection layer 122, for example air bubbles, acrylate, or hollow glass beads. Furthermore, by way of example, metallic nanoparticles, metals such as gold, silver, iron nanoparticles, or the like can be provided as light-scattering particles.

Alternatively or additionally, the close connection layer 122 can have a layer thickness of greater than 1 μm, for example a layer thickness of a plurality of μm. In various exemplary embodiments, the close connection layer 122 includes or is a lamination adhesive.

Alternatively or additionally, the close connection layer 122 can be designed in such a way that it includes an adhesive having a refractive index that is less than the refractive index of the cover 124. Such an adhesive can be for example a low refractive index adhesive such as, for example, an acrylate having a refractive index of approximately 1.3. However, the adhesive can also be a high refractive index adhesive which for example includes high refractive index, non-scattering particles and has a layer-thickness-averaged refractive index that approximately corresponds to the average refractive index of the organic functional layer structure 112, for example in a range of approximately 1.7 to approximately 2.0. Furthermore, a plurality of different adhesives can be provided which form an adhesive layer sequence.

Alternatively or additionally between the second electrode 114 and the close connection layer 122, an electrically insulating layer (not shown) can also be formed, for example SiN, for example having a layer thickness in a range of approximately 300 nm to approximately 1.5 μm, for example having a layer thickness in a range of approximately 500 nm to approximately 1 μm, in order to protect electrically unstable materials, during a wet-chemical process for example.

Alternatively or additionally a close connection layer 122 can be optional, for example if the cover 124 is formed directly on the second barrier layer 108, for example a cover 124 composed of glass that is formed by means of plasma spraying.

Alternatively or additionally a so-called getter layer or getter structure, for example a laterally structured getter layer, can be arranged (not illustrated) on or above the electrically active region 106.

Alternatively or additionally, the getter layer may include or be formed from a material that absorbs and binds substances that are harmful to the electrically active region 106. A getter layer may include or be formed from a zeolite derivative, for example. The getter layer can be formed as translucent, transparent or opaque and/or non-transmissive with respect to the electromagnetic radiation that is emitted and/or absorbed in the optically active region.

The getter layer can have a layer thickness of greater than approximately 1 μm, for example a layer thickness of a plurality of μm.

Alternatively or additionally the getter layer may include a lamination adhesive or the getter layer can be embedded in the close connection layer 122.

Alternatively or additionally, the cover 124 can be closely connected to the electrically active region 106 by means of the close connection layer 122 and can protect said region from harmful substances. The cover 124 can be for example a glass cover 124, a metal film cover 124 or a sealed plastics film cover 124. The glass cover 124 can be closely connected to the second barrier layer 108 or the electrically active region 106 for example by means of frit bonding (glass frit bonding/glass soldering/seal glass bonding) by means of a conventional glass solder in the geometric edge regions of the organic optoelectronic component 100.

Alternatively or additionally, the cover 124 and/or the close connection layer 122 can have a refractive index (for example at a wavelength of 633 nm) of 1.55.

It should be pointed out that, alternatively or additionally, one or more of the abovementioned layers arranged between the first electrode 110 and the second electrode 114 are optional.

Alternatively or additionally, the electrically active region 106 may include one, two or more functional layer structure units 112a, 112b and one, two or more charge generating layer structure(s) 115 between the layer structure units 112a, 112b, for example shown in FIG. 1B. The electrically active region 106 may include a first organic functional layer structure unit 112a arranged on the first electrode 110.

Furthermore, the electrically active region 106 may include a charge generating layer structure 115 arranged on the first organic functional layer structure unit 112a. Furthermore, the electrically active region 106 may include a second organic functional layer structure unit 112b on the charge generating layer structure 115. Furthermore, the second electrode 114 can be arranged on the second organic functional layer structure unit 112b. Additionally, the electrically active region 106 may include a third organic functional layer structure unit, a further charge generating layer structure and a fourth organic functional layer structure unit (not illustrated).

A charge generating layer structure may include one or a plurality of electron-conducting charge generating layer(s) and one or a plurality of hole-conducting charge generating layer(s). The electron-conducting charge generating layer(s) and the hole-conducting charge generating layer(s) can be formed in each case from an intrinsically conductive substance or a dopant in a matrix. The charge generating layer structure should be formed, with respect to the energy levels of the electron-conducting charge generating layer(s) and the hole-conducting charge generating layer(s), in such a way that electron and hole can be separated at the interface between an electron-conducting charge generating layer and a hole-conducting charge generating layer. The charge generating layer structure can furthermore have a diffusion barrier between adjacent layers.

An organic light emitting diode including the first electrode 110, the second electrode 114 and two functional layer structure units 112a, 112b, wherein a charge generating layer structure 115 is arranged between the two functional layer structure units 112a, 112b, can also be referred to as a doubly stacked organic light emitting diode. A doubly stacked organic light emitting diode can also be regarded as two organic light emitting diodes connected in series, wherein the two organic light emitting diodes connected in series are connected by means of a charge generating layer structure 115. Alternatively or additionally, three, four, five, for example ten, organic light emitting diodes can also be stacked one above another, or connected in series with one another, by means of a plurality of charge generating layer structures. In this case, the respective charge generating layer structures can be formed identically or differently with respect to one another.

Alternatively or additionally, the functional layer structure units 112a, 112b can in each case be formed like the organic functional layer structure 112 described further above. Alternatively or additionally, the layers of the functional layer structure units 112a, 112b can in each case include the same material combinations.

It should be noted that, in the case where the organic light emitting diode includes one, two or more charge generating layer structure(s), the respective charge generating layer structure(s) are formed in such a way that they have no electrical terminal, i.e. are free of component-external terminals.

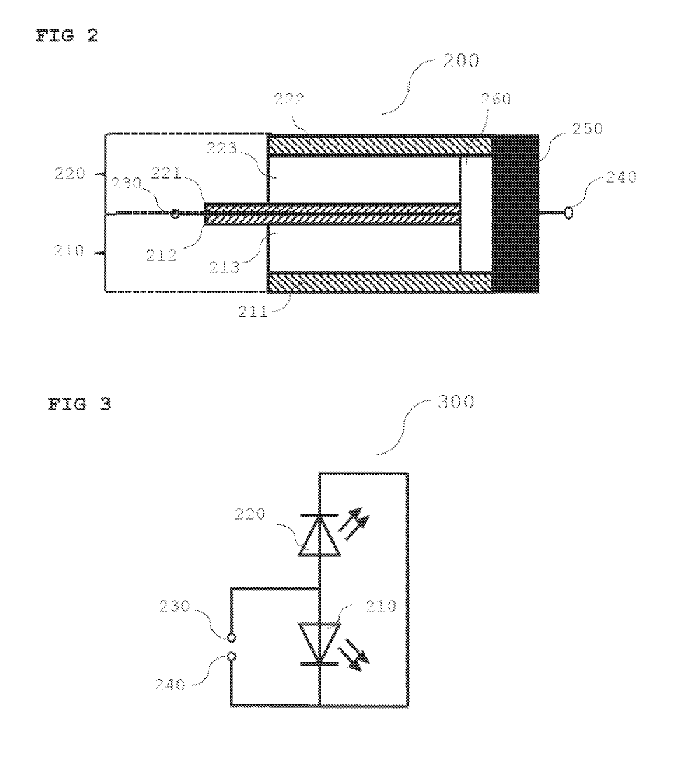

FIG. 2 shows one exemplary embodiment of an optoelectronic component device. The optoelectronic component device 200 includes a first organic light emitting diode 210 (identified by dashed lines in FIG. 2) and a second organic light emitting diode 220 (identified by dashed lines in FIG. 2), which are connected to one another in physical contact one above the other. The first organic light emitting diode 210 is electrically connected in parallel with the second organic light emitting diode 220.

The first organic light emitting diode 210 includes a first electrode 211, an organic functional layer structure 213 and second electrode 212.

In accordance with one development, the first electrode 211 of the first organic light emitting diode 210 is formed like the above-described second electrode 114 of the organic light emitting diode 100.

In accordance with one development, the organic functional layer structure 213 of the first organic light emitting diode 210 is formed in accordance with one exemplary embodiment of the organic functional layer structure 112 of the organic light emitting diode 100.

In accordance with one development, the second electrode 212 of the first organic light emitting diode 210 is formed in accordance with an above-described exemplary embodiment of the first electrode 110 of the organic light emitting diode 100. Furthermore, the second electrode 212 is formed as an anode of the first organic light emitting diode 210.

The second organic light emitting diode 220 includes a first electrode 221, an organic functional layer structure 223 and a second electrode 222.

In accordance with one development, the first electrode 221 of the second organic light emitting diode 220 is formed like the second electrode 114 of the organic light emitting diode 100.

In accordance with one development, the organic functional layer structure 223 of the second organic light emitting diode 220 is formed in accordance with one exemplary embodiment of the organic functional layer structure 112 of the organic light emitting diode 100.

In accordance with one development, the second electrode 222 of the second organic light emitting diode 220 is formed in accordance with an above-described exemplary embodiment of the second electrode 114 of the organic light emitting diode 100. Furthermore, the second electrode 222 is formed as a cathode of the second organic light emitting diode 220.

In accordance with one embodiment, the first organic light emitting diode 210 and the second organic light emitting diode 220 have at least an approximately identical or identical electronic diode characteristic and/or an approximately identical or identical electronic diode characteristic variable. An electronic diode characteristic can furthermore also be designated as a current-voltage characteristic curve, for example also designated as IU characteristic curve, for example also designated as an IU characteristic, for example also designated as IU curve. The first organic light emitting diode has a current-voltage characteristic curve such that the current-voltage characteristic curve of the first organic light emitting diode has similar values, for example in a range of 10% to 15%, compared with those of the current-voltage characteristic curve of the second organic light emitting diode.

The first organic light emitting diode 210 is formed in such a way that it provides light having a first hue during operation. The second organic light emitting diode 220 is formed in such a way that it provides light having a second hue during operation. In accordance with one embodiment, the first hue and the second hue are approximately identical or identical. The first hue has a similar value, for example in a range of 10% to 15%, compared with that of the second hue.

In accordance with one development, the second electrode 212 of the first organic light emitting diode 210 and the first electrode 221 of the second organic light emitting diode 220 are electrically connected to one another in such a way that they form a common electrode. Furthermore, the common electrode has a first electrical terminal. A common first electrical potential 230 can be applied by means of the first electrical terminal. The first electrical potential 230 can be provided by an energy source, for example a current source or a voltage source. The first electrical potential 230 can be for example the ground potential or some other predefined reference potential.

In accordance with one development, the common electrode is formed from or includes an at least translucent material.

In accordance with one development, the second electrode 212 of the first organic light emitting diode 210 is an anode of the first organic light emitting diode 210, and the first electrode 221 of the second organic light emitting diode 220 is an anode of the second organic light emitting diode 220. Furthermore, the organic functional layer structure 213 of the first organic light emitting diode 210 is formed in accordance with one exemplary embodiment of the organic functional layer structure 112 of the organic light emitting diode 100, wherein the layers of the organic functional layer structure 213 of the first organic light emitting diode 210 are arranged oppositely to the layers of the organic functional layer structure 112 of the organic light emitting diode 100. By way of example, an electron injection layer is arranged on the first electrode 211 and an electron transport layer is arranged on the electron injection layer. Furthermore, an emitter layer is arranged on the electron transport layer and a hole transport layer is arranged on the emitter layer and a hole injection layer is arranged on the hole transport layer. The electron injection layer is formed in accordance with an above-described exemplary embodiment of the electron injection layer of the organic light emitting diode 100. The electron transport layer is formed in accordance with an above-described exemplary embodiment of the electron transport layer 116 of the organic light emitting diode 100. The emitter layer is formed in accordance with an above-described exemplary embodiment of the emitter layer 118 of the organic light emitting diode 100. The hole transport layer is formed in accordance with an above-described exemplary embodiment of the hole transport layer 120 of the organic light emitting diode 100. The hole injection layer is formed in accordance with an above-described exemplary embodiment of the hole injection layer of the organic light emitting diode 100. Furthermore, the first electrode 211 of the first organic light emitting diode 210 is formed as a cathode of the first organic light emitting diode 210, and the second electrode 222 of the second organic light emitting diode 220 is formed as a cathode of the second organic light emitting diode 220.

In accordance with one development, the first electrode 211 of the first organic light emitting diode 210 and the second electrode 222 of the second organic light emitting diode 220 have a common electrical potential 240. The common electrical potential of the first electrode 211 of the first organic light emitting diode 210 and the second electrode 222 of the second organic light emitting diode 220 is furthermore also designated as second electrical potential 240.

In accordance with one development, the first electrode 211 of the first organic light emitting diode 210 and the second electrode 222 of the second organic light emitting diode 220 are arranged congruently one above the other, and the second electrode 212 of the first organic light emitting diode 210 and the first electrode 221 of the second organic light emitting diode 220 are arranged congruently one above the other.

The first light of the first organic light emitting diode 210 and the second light of the second organic light emitting diode 220 can have a white hue. Alternatively, the first light and the second light can have a red, green or blue hue.

Alternatively or additionally, the IU curve of the first organic light emitting diode 210 can have the same shape as the IU curve of the second organic light emitting diode 220.

By way of example, a current, a voltage and/or a brightness at an operating point of the organic light emitting diodes 210, 220 can be designated as diode characteristic variable.

Furthermore, by way of example, a maximum permissible reverse voltage, a maximum peak current in the forward direction and/or a maximum continuous current in the forward direction can also be designated as diode characteristic variable. The first organic light emitting diode 210 has a diode characteristic variable such that the diode characteristic variable of the first organic light emitting diode has a similar value, for example in a range of 10% to 15%, compared with the value of the diode characteristic variable of the second organic light emitting diode 220.

Alternatively or additionally, the common electrode can be formed in an integral fashion. Alternatively or additionally, the second electrode 212 of the first organic light emitting diode 210 and the first electrode 221 of the second organic light emitting diode 220 can be electrically conductively connected to one another by means of a conductive connection means, for example by means of a soldering tin.

Alternatively or additionally, the first electrode 211 of the first organic light emitting diode 210 can be formed on a carrier, wherein the carrier can be formed in accordance with one exemplary embodiment of the carrier 102 of the organic light emitting diode 100. Alternatively or additionally, the first electrode 211 of the first organic light emitting diode 210 can be formed in a self-supporting fashion in accordance with one of the exemplary embodiments of the carrier 102 and/or of the first electrode 110 of the organic light emitting diode 100.

Alternatively or additionally, the second electrical potential 240 can be provided by the same energy source as, or a different energy source than, the first electrical potential 230. The second electrical potential 240 can be different than the first electrical potential 230. The second electrical potential 240 can have for example a value such that the difference with respect to the electrical potential has a value in a range of approximately 1.5 V to approximately 20 V, for example a value in a range of approximately 2.5 V to approximately 15 V, for example a value in a range of approximately 3 V to approximately 12 V. Alternatively or additionally, the first electrode 211 of the first organic light emitting diode 210 and the second electrode 222 of the second organic light emitting diode 220 are electrically conductively connected to one another by means of an electrically conductive connection means 250. Alternatively or additionally, an electrically insulating substance 260 can be formed between the electrically conductive connection means 250 and the organic functional layer structure 213 and the second electrode 212 of the first organic light emitting diode 210 and the first electrode 221 and the organic functional layer structure 223 of the second organic light emitting diode 220. A short circuit between the first electrical potential and the second electrical potential can be prevented by means of the electrically insulating substance.

Alternatively, the first electrode 211 of the first organic light emitting diode 210 and the second electrode 222 of the second organic light emitting diode 220 are arranged one above the other in a laterally offset manner. Alternatively, the second electrode 212 of the first organic light emitting diode 210 and the first electrode 221 of the second organic light emitting diode 220 are arranged one above the other in a laterally offset manner.

Forming two or more stacked organic light emitting diodes, as described thoroughly above and below, wherein the organic light emitting diodes have an approximately identical or identical electrical diode characteristic and/or an approximately identical or identical diode characteristic variable, affords the advantage for example, that the resulting optoelectronic component device has a longer lifetime. By way of example, in the case of a failure or in the case of a reduced function of one of the organic light emitting diodes, said organic light emitting diode can be overdriven in such a way that the optoelectronic component device is still functional. By way of example, the organic light emitting diodes can be adapted to one another with regard to some of their electrical properties during operation, as a result of which the lifetime of the optoelectronic component device is increased.

FIG. 3 shows an equivalent circuit diagram of one exemplary embodiment of an optoelectronic component device, which for example largely corresponds to the exemplary embodiment shown in FIG. 2.

The equivalent circuit diagram 300 shows the first organic light emitting diode 210 and the second organic light emitting diode 220, wherein the first organic light emitting diode 210 and the second organic light emitting diode 220 are arranged in a parallel connection. Furthermore, the first electrical potential 230 and the second electrical potential 240 can be applied in such a way that the first organic light emitting diode 210 and the second organic light emitting diode 220 are operable in each case in the forward direction or are operable in each case in the reverse direction.

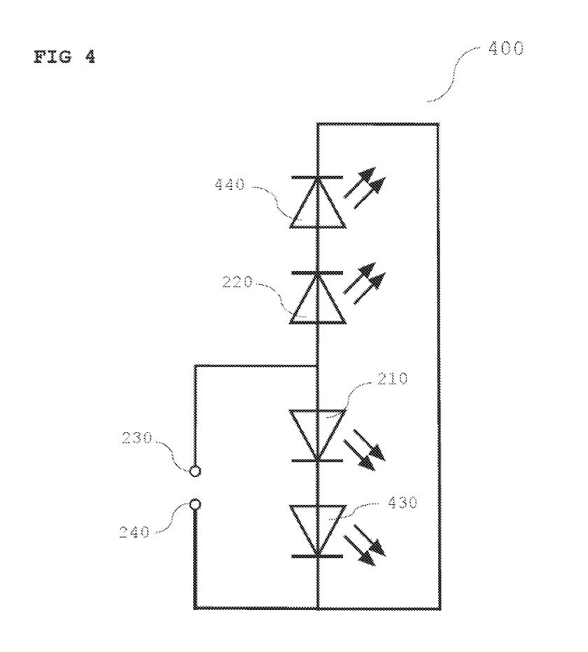

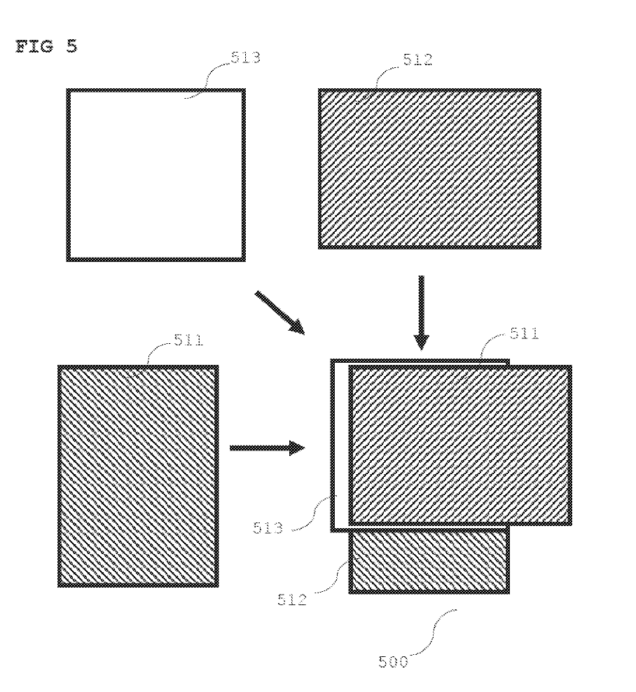

FIG. 4 shows an equivalent circuit diagram of one exemplary embodiment of an optoelectronic component device, which for example largely corresponds to the equivalent circuit diagram shown in FIG. 3.

In accordance with one development, the optoelectronic component device 400 includes one or a plurality of further organic light emitting diodes connected in series with the first organic light emitting diode 210.

In accordance with one development, the optoelectronic component device includes one or a plurality of further organic light emitting diodes connected in series with the second organic light emitting diode 220.

The equivalent circuit diagram 400 shows a third organic light emitting diode 430, which is connected in series with the first organic light emitting diode 210. The third organic light emitting diode 430 is formed in accordance with an above-described exemplary embodiment of the organic light emitting diode 100. Furthermore, the equivalent circuit diagram 400 shows a fourth organic light emitting diode 440, which is connected in series with the second organic light emitting diode 220. The fourth organic light emitting diode 440 is formed in accordance with an above-described exemplary embodiment of the organic light emitting diode 100.

In accordance with one exemplary embodiment, the first organic light emitting diode 210 and the third organic light emitting diode 430 are formed as a doubly stacked organic light emitting diode, wherein the first organic light emitting diode 210 and the third organic light emitting diode 430 are connected by means of a first charge generating layer structure. Furthermore, the second organic light emitting diode 220 and the fourth organic light emitting diode 440 are formed as a doubly stacked organic light emitting diode, wherein the second organic light emitting diode 220 and the fourth organic light emitting diode 440 are connected by means of a second charge generating layer structure. The organic functional layer structure 213 of the first organic light emitting diode 210 is connected to the organic functional layer structure of the third organic light emitting diode 430 by means of the first charge generating layer structure. To put it another way, the first charge generating layer structure is arranged between the organic functional layer structure 213 of the first organic light emitting diode 210 and the organic functional layer structure of the third organic light emitting diode 430. The organic functional layer structure 223 of the second organic light emitting diode 220 is connected to the organic functional layer structure of the fourth organic light emitting diode 430 by means of a charge generating layer structure. To put it another way, the second charge generating layer structure is arranged between the organic functional layer structure 223 of the second organic light emitting diode 220 and the organic functional layer structure of the fourth organic light emitting diode 440. Furthermore, the second electrode 212 of the first organic light emitting diode 210 is formed as an anode. Furthermore, the organic functional layer structure 213 of the first organic light emitting diode 210 and the organic functional layer structure of the third organic light emitting diode are formed in accordance with the layer sequence described with regard to FIG. 1. Furthermore, the first electrode 221 of the second organic light emitting diode 220 is formed as an anode. Furthermore, the organic functional layer structure 223 of the second organic light emitting diode 220 and the organic functional layer structure of the fourth organic light emitting diode are formed oppositely relative to the layer sequence described in FIG. 1. Furthermore, the first organic light emitting diode 210 and the second organic light emitting diode 220 are stacked one above the other in such a way that the anode of the first organic light emitting diode 210 is in direct connect with the anode of the second organic light emitting diode 220. Furthermore, the second electrical potential 240 can be applied to the cathode of the third organic light emitting diode 430 and to the cathode of the fourth organic light emitting diode 440. Furthermore, the first electrical potential 230 can be applied to the anode of the first organic light emitting diode 210 and to the anode of the second organic light emitting diode 220.

Alternatively or additionally, the further organic light emitting diodes connected in series with the first organic light emitting diode 210 can be formed like the first organic light emitting diode 210. Alternatively or additionally, further organic light emitting diodes, for example one, two, three, four or five, for example ten, further organic light emitting diodes, can be arranged on the first organic light emitting diode 210, wherein the further organic light emitting diodes are connected to one another by means of charge generating layer structures.

Alternatively or additionally, the further organic light emitting diodes connected in series with the second organic light emitting diode 220 can be formed like the second organic light emitting diode 220. Alternatively or additionally, further organic light emitting diodes, for example one, two, three, four or five, for example ten, further organic light emitting diodes, can be arranged on the second organic light emitting diode 220, wherein the further organic light emitting diodes are connected to one another by means of charge generating layer structures.

Alternatively or additionally, the second electrical potential 240 can be applied to the respective outermost electrodes, for example the cathodes, of the layer stack.

Alternatively, the outer electrodes, that is to say, for example, for the case of a total of four organic light emitting diodes 210, 220, 430 and 440 stacked one on top of another, the second electrode of the fourth organic light emitting diode 440 and the first electrode of the third organic light emitting diode 430, can also be formed as anodes. In this case, the inner electrodes, that is to say the second electrode 212 of the first organic light emitting diode 210 and the first electrode 221 of the second organic light emitting diode 220, are formed as cathodes.

FIG. 5 shows one exemplary embodiment of an optoelectronic component device, which for example largely corresponds to the exemplary embodiment shown in FIG. 2.

In accordance with one exemplary embodiment, the optoelectronic component device 500 includes an anode and at least one further anode. Furthermore, the optoelectronic component device 500 includes at least one cathode. Furthermore, the optoelectronic component device 500 includes an organic functional layer structure and at least one further organic functional layer structure. The organic functional layer structure is arranged on the anode. The at least one cathode is arranged on the organic functional layer structure. The at least one further organic functional layer structure is arranged on the at least one cathode. The at least one further anode is arranged on the at least one further organic functional layer structure.

In accordance with one development, the above-described layer sequence in the scheme described above is continued up to an arbitrary stack height. In accordance with one development, the anodes are in each case formed in such a way that the same electrical potential, for example the first electrical potential 230 can be applied to the anodes. Furthermore, the cathodes are in each case formed in such a way that the same electrical potential, for example the second electrical potential 240, can be applied to the cathodes. In other words, in accordance with one development, a plurality of organic light emitting diodes are stacked one above another, wherein the plurality of organic light emitting diodes in each case include a cathode, an organic functional layer system and an anode. The plurality of organic light emitting diodes are interconnected with one another by means of a parallel connection.

In accordance with one exemplary embodiment and as illustrated in FIG. 5, the optoelectronic component device 400 includes an anode 511, a cathode 512 and an organic functional layer system 513. The anode 511 is formed in accordance with one exemplary embodiment of the first electrode 110. The cathode is formed in accordance with one exemplary embodiment of the second electrode 114. The organic functional layer structure 513, for example also designated as organic system, is formed in accordance with one exemplary embodiment of the organic functional layer system 112. An optoelectronic component device can be formed from the individual component parts mentioned (illustrated by means of the arrows in FIG. 5). In accordance with one exemplary embodiment, a stack sequence anode 511/organic system 513/cathode 512/organic system 513/anode 511 is formed. In accordance with this exemplary embodiment, the organic functional layer structure 513 is arranged on the anode 511. The cathode 512 is arranged on the organic functional layer structure 513. A further organic functional layer structure is in turn arranged on the cathode 512, said further organic functional layer structure being formed like the organic functional layer structure 513 and therefore also being designated hereinafter as organic functional layer structure 513.

In principle, it is possible to continue this stack sequence arbitrarily, for example by means of the following layer sequence, anode 511/organic system 513/cathode 512/organic system 513/anode 511/organic system 513/cathode 512 (for example also designated as A/C/A/C OLED), for example by means of the following layer sequence, cathode 512/organic system 513/anode 511/organic system 513/cathode 512/organic system 513/anode 511/organic system 513/cathode 512 (for example also designated as C/A/C/A/C OLED).

What is special about this construction is that the voltage required for operating an OLED can be reduced, without losing the advantages of the multiple stacking. To put it another way, an n-fold stacked OLED can still be operated with the voltage of an unstacked OLED. OLEDs having a long lifetime can thus be produced, which can nevertheless be supplied by customary voltage sources. No additional contacts for driving are required.

The cathodes, the anodes and the organic functional layer system can have any desired shapes. For example a rectangular shape (illustrated in FIG. 5). Alternatively or additionally, the cathodes, the anodes and the organic functional layer system can have a circular shape or a shape similar to that of a circle. Alternatively or additionally, the anode 511, the cathode 512 and the organic functional layer structure 513 can also be formed in a trapezoidal or pyramidal fashion. Alternatively or additionally, the anode 511, the cathode 512 and the organic functional layer structure 513 can have the shape of a circle segment or the shape of an annulus.

As described above, the stack sequence can be repeated as often as desired, wherein the simplest stack sequence constitutes the following layer sequence: anode 511/organic system 513/cathode 512/organic system 513/anode 511.

Alternatively or additionally, the anode(s) 511, the cathode(s) 512 and the organic functional layer system(s) 513 can be formed as at least translucent.

Alternatively or additionally, the carrier 102 can be arranged at an end of the layer stack.

Alternatively or additionally, an electrode arranged at the end of the layer stack can be formed in accordance with one exemplary embodiment of the carrier 102.

Alternatively or additionally, the anodes of the optoelectronic component device 500 can be formed identically or differently with respect to one another. Alternatively or additionally, the cathodes of the optoelectronic component device 500 can be formed identically or differently with respect to one another. Alternatively or additionally, the organic functional layer structures of the optoelectronic component device 500 can be formed identically or differently with respect to one another.

Alternatively or additionally, one or a plurality of organic light emitting diodes in the layer stack described above can be formed as for example doubly, for example triply, for example quadruply, for example ten-fold, stacked organic light emitting diode.

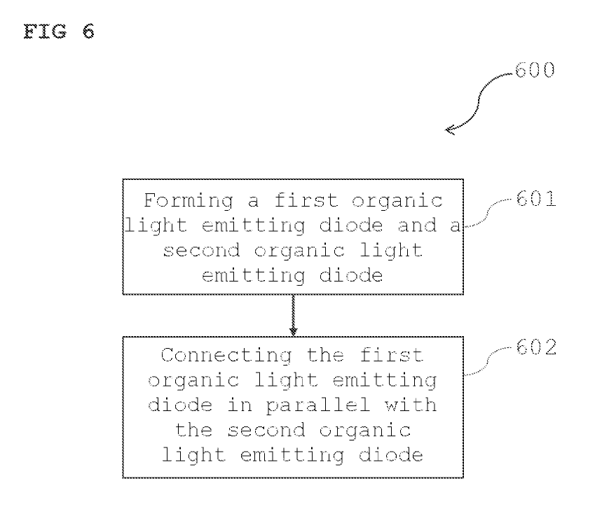

FIG. 6 shows a flow diagram of a method for producing an optoelectronic component device, for example the optoelectronic component device explained above.

The method 600 for producing an optoelectronic component device includes forming 601 a first organic light emitting diode 210 and a second organic light emitting diode 220 in such a way that the first organic light emitting diode 210 and the second organic light emitting diode 220 are connected to one another in physical contact one above the other. The method furthermore includes connecting the first organic light emitting diode 210 in parallel with the second organic light emitting diode 220. The first organic light emitting diode 210 and the second organic light emitting diode 220 are formed in such a way that they have at least an approximately identical or identical electronic diode characteristic and/or an approximately identical or identical electronic diode characteristic variable.

The method 600 for producing an optoelectronic component device includes forming 601 a first organic light emitting diode 210 and a second organic light emitting diode 220 in such a way that the first organic light emitting diode 210 and the second organic light emitting diode 220 are connected to one another in physical contact one above the other. The method furthermore includes connecting the first organic light emitting diode 210 in parallel with the second organic light emitting diode 220. The first organic light emitting diode 210 is formed in such a way that it provides a first light having a first hue, and the second organic light emitting diode 220 is formed in such a way that it provides a second light having a second hue. The first organic light emitting diode 210 and the second organic light emitting diode 220 are formed in such a way that the first hue and the second hue are approximately identical or identical. This makes it possible to produce an optoelectronic component device having an increased lifetime.

In accordance with one development, the method 600 furthermore includes forming one or a plurality of further organic light emitting diodes connected in series with the first organic light emitting diode 210.

In accordance with one development, the method 600 furthermore includes forming one or a plurality of further organic light emitting diodes connected in series with the second organic light emitting diode 220.

Forming 601 the first organic light emitting diode 210 and the second organic light emitting diode 220 includes forming the first organic light emitting diode 210 and forming the second organic light emitting diode 220. The first organic light emitting diode 210 is formed in accordance with an above-described exemplary embodiment of the first organic light emitting diode 210. The second organic light emitting diode 220 is formed in accordance with an above-described exemplary embodiment of the second organic light emitting diode 220.

In accordance with one development, forming the first organic light emitting diode 210 includes forming a first electrode 211, forming an organic functional layer structure 213 and forming a second electrode 212, wherein the organic functional layer structure 212 is arranged on or above the first electrode 211 and wherein the second electrode 212 is arranged on or above the organic functional layer structure 213. The first electrode 211 is formed in accordance with an above-described exemplary embodiment of the first electrode 211 of the first organic light emitting diode 210. The second electrode 212 is formed in accordance with an above-described exemplary embodiment of the second electrode 212 of the first organic light emitting diode 210. The organic functional layer structure 213 is formed in accordance with an above-described exemplary embodiment of the organic functional layer structure 213 of the first organic light emitting diode 210.

In accordance with one development, forming the second organic light emitting diode 220 includes forming a first electrode 221, forming an organic functional layer structure 223 and forming a second electrode 222, wherein the organic functional layer structure 223 is arranged on or above the first electrode 221 and wherein the second electrode 222 is arranged on or above the organic functional layer structure 223. The first electrode 221 is formed in accordance with an above-described exemplary embodiment of the first electrode 221 of the second organic light emitting diode 220. The second electrode 222 is formed in accordance with an above-described exemplary embodiment of the second electrode 222 of the second organic light emitting diode 220. The organic functional layer structure 223 is formed in accordance with an above-described exemplary embodiment of the organic functional layer structure 223 of the second organic light emitting diode 220.

In accordance with one development, the second electrode 212 of the first organic light emitting diode 210 and the first electrode 221 of the second organic light emitting diode 220 are electrically connected to one another in such a way that they form a common electrode.

In accordance with one development, the common electrode is formed from an at least translucent material or is formed in such a way that the common electrode includes a translucent material.

In accordance with one development, the first electrode 211 of the first organic light emitting diode 210 and the second electrode 222 of the second organic light emitting diode 220 are arranged congruently one above the other, and the second electrode 212 of the first organic light emitting diode 210 and the first electrode 221 of the second organic light emitting diode 220 are arranged congruently one above the other.

Alternatively or additionally, by means of the back-to-back processing of two half-OLEDs that share an electrode, it is possible to produce an OLED system in which the voltage required for operation is reduced to the operating voltage of an individual diode. That is to say that one OLED alone has the same operating voltage as two ACA linked OLEDs. In principle, further reductions are also possible: in principle, firstly a semitransparent anode is applied in this case. Said anode can be constructed from TCOs (transparent conductive oxides) or from thin metal layers. A multiply stacked OLED is then processed. A semitransparent cathode is then vapor-deposited instead of a nontransparent cathode. The lower OLED is then vapor-deposited again in an inverted manner. There are then two possibilities: firstly, the OLED can be terminated by a nontransparent anode or, secondly, a further semitransparent intermediate electrode can be vapor-deposited, an OLED is in this case vapor-deposited in the original configuration and a decision can then be taken once again as to whether the process is intended to be continued or interrupted. In this case, all the anodes are not laterally separated; the same applies to all the cathodes. Consequently, from outside it is not evident from the device that it is a C|A|C|A OLED.

In various exemplary embodiments, the method 600 for producing the optoelectronic component device can have features of the optoelectronic component and the optoelectronic component device can have features of the method for producing the optoelectronic component device in such a way and insofar as the features are expediently applicable in each case.

The present disclosure is not restricted to the exemplary embodiments indicated. By way of example, the exemplary embodiments shown in FIGS. 1, 2, 3, 4, 5 and 6 can be combined with one another.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic component device comprising:
a first organic light emitting diode with a first electrode, an organic functional layer structure and a second electrode, wherein the organic functional layer structure is arranged on or above the first electrode and wherein the second electrode is arranged on or above the organic functional layer structure, and a second organic light emitting diode with a first electrode, an organic functional layer structure and a second electrode, wherein the organic functional layer structure is arranged on or above the first electrode and wherein the second electrode is arranged on or above the organic functional layer structure, wherein the second electrode of the first organic light emitting diode and the first electrode of the second organic light emitting diode are electrically conductively connected to one another by means of a conductive connection means so that the first organic light emitting diode and the second organic light emitting diode are connected to one another in physical contact one above the other;
wherein the optoelectronic component device is designed as a top or bottom emitter;
wherein the first organic light emitting diode is electrically connected in parallel with the second organic light emitting diode; and
wherein the first organic light emitting diode and the second organic light emitting diode have at least an approximately identical or identical electronic diode characteristic and/or an approximately identical or identical electronic diode characteristic variable; or
wherein the first organic light emitting diode provides a first light having a first hue and the second organic light emitting diode provides a second light having a second hue.

2. (canceled)

3. The optoelectronic component device as claimed in claim 1, further comprising
one or a plurality of further organic light emitting diodes connected in series with the first organic light emitting diode.

4. The optoelectronic component device as claimed in claim 1, further comprising
one or a plurality of further organic light emitting diodes connected in series with the second organic light emitting diode.

5-6. (canceled)

7. The optoelectronic component device as claimed in claim 1,
wherein the second electrode of the first organic light emitting diode and the first electrode of the second organic light emitting diode are electrically connected to one another in such a way that they form a common electrode.

8. The optoelectronic component device as claimed in claim 1,
wherein the common electrode is formed from or comprises an at least translucent material.

9. The optoelectronic component device as claimed in claim 1,
wherein the second electrode of the first organic light emitting diode is an anode of the first organic light emitting diode and wherein the first electrode of the second organic light emitting diode is an anode of the second organic light emitting diode.

10. The optoelectronic component device as claimed in claim 1,
wherein the first electrode of the first organic light emitting diode and the second electrode of the second organic light emitting diode have a common electrical potential.

11. The optoelectronic component device as claimed in claim 1,
wherein the first electrode of the first organic light emitting diode and the second electrode of the second organic light emitting diode are arranged congruently one above the other, and wherein the second electrode of the first organic light emitting diode and the first electrode of the second organic light emitting diode are arranged congruently one above the other.

12. A method for producing an optoelectronic component device comprising a first organic light emitting diode and a second organic light emitting diode, the method comprising:
forming a first organic light emitting diode with a first electrode, an organic functional layer structure and a second electrode, wherein the organic functional layer structure is arranged on or above the first electrode and wherein the second electrode is arranged on or above the organic functional layer structure, and forming a second organic light emitting diode with a first electrode, an organic functional layer structure and a second electrode, wherein the organic functional layer structure is arranged on or above the first electrode and wherein the second electrode is arranged on or above the organic functional layer structure, wherein the second electrode of the first organic light emitting diode and the first electrode of the second organic light emitting diode are electrically conductively connected to one another by means of a conductive connection means so that the first organic light emitting diode and the second organic light emitting diode are connected to one another in physical contact one above the other;
wherein the optoelectronic component device is designed as a top or bottom emitter;
wherein the first organic light emitting diode is electrically connected in parallel with the second organic light emitting diode; and
wherein the first organic light emitting diode and the second organic light emitting diode are formed in such a way that they have at least an approximately identical or identical electronic diode characteristic and/or an approximately identical or identical electronic diode characteristic variable; or wherein the first organic light emitting diode and the second organic light emitting diode are formed in such a way that the first hue and the second hue are approximately identical or identical.

13. (canceled)

14. The method as claimed in claim 12, further comprising
forming one or a plurality of further organic light emitting diodes connected in series with the first organic light emitting diode.

15. The method as claimed in claim 12, further comprising
forming one or a plurality of further organic light emitting diodes connected in series with the second organic light emitting diode.

16-17. (canceled)

18. The method as claimed in claim 12,
wherein the second electrode of the first organic light emitting diode and the first electrode of the second organic light emitting diode are electrically connected to one another in such a way that they form a common electrode.

19. The method as claimed in claim 18,
wherein the common electrode is formed from an at least translucent material or is formed in such a way that the common electrode comprises a translucent material.

20. The method as claimed in claim 12,
wherein the first electrode of the first organic light emitting diode and the second electrode of the second organic light emitting diode are arranged congruently one above the other, and wherein the second electrode of the first organic light emitting diode and the first electrode of the second organic light emitting diode are arranged congruently one above the other.

21. The optoelectronic component device as claimed in claim 1, further comprising:
one or a plurality of further organic light emitting diodes connected in series with the first organic light emitting diode, and
one or a plurality of further organic light emitting diodes connected in series with the second organic light emitting diode.

22. The optoelectronic component device as claimed in claim 1,
wherein the second electrode of the first organic light emitting diode is an anode of the first organic light emitting diode and wherein the first electrode of the second organic light emitting diode is an anode of the second organic light emitting diode, and
wherein the first electrode of the first organic light emitting diode and the second electrode of the second organic light emitting diode have a common electrical potential.

23. The optoelectronic component device as claimed in claim 1,
wherein the second electrode of the first organic light emitting diode is an anode of the first organic light emitting diode and wherein the first electrode of the second organic light emitting diode is an anode of the second organic light emitting diode, and
wherein the first electrode of the first organic light emitting diode and the second electrode of the second organic light emitting diode are arranged congruently one above the other, and wherein the second electrode of the first organic light emitting diode and the first electrode of the second organic light emitting diode are arranged congruently one above the other.

24. The method as claimed in claim 12,
wherein the second electrode of the first organic light emitting diode and the first electrode of the second organic light emitting diode are electrically connected to one another in such a way that they form a common electrode,
wherein the first electrode of the first organic light emitting diode and the second electrode of the second organic light emitting diode are arranged congruently one above the other, and wherein the second electrode of the first organic light emitting diode and the first electrode of the second organic light emitting diode are arranged congruently one above the other.

25. The method as claimed in claim 24,
wherein the common electrode is formed from an at least translucent material or is formed in such a way that the common electrode comprises a translucent material.
